(19) United States
(12) Patent Application Publication
(10) Pub. No.: US 2025/0004066 A1
(43) Pub. Date: Jan. 2, 2025

(54) BATTERY DETECTION METHOD, APPARATUS, AND DEVICE, AND STORAGE MEDIUM

(71) Applicants: CONTEMPORARY AMPEREX FUTURE ENERGY RESEARCH INSTITUTE (SHANGHAI) LIMITED, Shanghai (CN); CONTEMPORARY AMPEREX TECHNOLOGY CO., LIMITED, Ningde (CN)

(72) Inventor: Qiujin JIN, Shanghai (CN)

(21) Appl. No.: 18/753,530

(22) Filed: Jun. 25, 2024

(30) Foreign Application Priority Data
Jun. 29, 2023 (CN) 202310786385.8

(51) Int. Cl. G01R 31/396; G01R 31/36; G01R 31/382; H01M 10/48

(52) U.S. Cl. CPC G01R 31/396; G01R 31/3648; G01R 31/382; H01M 10/482

(57) ABSTRACT

A battery detection method includes: acquiring state of charge values of each battery cell in a battery system at different time points within a preset time; and performing multiple linear regression analysis based on state of charge values of a reference battery cell, the state of charge values of the battery cells, and timestamps at corresponding time points to obtain a consistency detection result of the battery cells in the battery system.

### CROSS-REFERENCE TO RELATED APPLICATION

This application claims priority to Chinese Application No. 202310786385.8, filed on Jun. 29, 2023, the entire content of which is incorporated herein by reference.

### TECHNICAL FIELD

This application relates to the field of battery technologies, and specifically, to a battery detection method, apparatus, and device, and a storage medium.

### BACKGROUND

Generally, to implement consistency detection of battery packs, it is needed to separately calculate the capacity/self-discharge of each battery cell. However, it is unable to record a significant amount of historical data in a BMS battery management system for capacity/self-discharge calculation. It is easier to implement the calculation in the cloud, but obtaining accurate cumulative capacity data in the cloud is often challenging, and more accurate consistency detection of battery packs cannot be implemented.

### SUMMARY

In view of the foregoing problems, this application provides a battery detection method, apparatus, and device, and a storage medium, so as to address the issue that consistency detection cannot be performed for battery packs more accurately.

According to a first aspect, this application provides a battery cell detection method including:
acquiring state of charge values of each battery cell in a battery system at different time points within a preset time;
selecting a reference battery cell from the battery cells; and
performing multiple linear regression analysis based on state of charge values of the reference battery cell, the state of charge values of each battery cell, and timestamps at corresponding time points to obtain a consistency detection result of the battery cells in the battery system.

In technical solutions of embodiments of this application, a consistency detection result of the battery cells in the battery system is achieved by just selecting a reference battery cell from the battery cells and comparing the reference battery cell with the battery cells, without using accurate cumulative capacity data, obtaining a variation in the state of charge values based on the cumulative capacity data and obtaining the consistency detection result of the battery cells based on the variation in the state of charge values. Even without the capacity data, a relative result can be obtained through calculation, thus consistency of the battery cells is calculated, and the accuracy of battery detection is improved.

In some embodiments, the performing multiple linear regression analysis based on state of charge values of the reference battery cell, the state of charge values of each battery cell, and timestamps at corresponding time points to obtain a consistency detection result of the battery cells in the battery system includes:
acquiring a first matrix established based on state of charge values of the reference battery cell, and acquiring a second matrix established based on the state of charge values of each battery cell and timestamps at corresponding time points;
performing linear regression calculations based on the first matrix and the second matrix to obtain corresponding relative battery capacity and relative self-discharge of each battery cell; and
obtaining a consistency detection result of the battery cells in the battery system based on the corresponding relative battery capacity and relative self-discharge of each battery cell.

In the technical solution of these embodiments of this application, the corresponding relative battery capacity and relative self-discharge of each battery cell are obtained based on the state of charge values of the reference battery cell, the state of charge values of each battery cell, and the timestamps at the corresponding time points. In this way, the corresponding relative battery capacity and relative self-discharge of each battery cell are obtained using the characteristic that the battery cells in the battery system have the same discharge capacity, without using accurate cumulative capacity data, and thus the accuracy of battery detection is improved.

In some embodiments, the performing linear regression calculations based on the first matrix and the second matrix to obtain corresponding relative battery capacity and relative self-discharge of each battery cell further includes:
performing linear regression calculations based on the first matrix and the second matrix to obtain a regression result including a first regression coefficient and a second regression coefficient; and
using the first regression coefficient as a corresponding relative battery capacity of each battery cell and using the second regression coefficient as a corresponding relative self-discharge of each battery cell based on the regression result.

In the technical solution of these embodiments of this application, the corresponding relative battery capacity and relative self-discharge of each battery cell are obtained based on the statistically calculated positive correlation between the corresponding relative battery capacity and relative self-discharge of each battery cell and the state of charge values of the reference battery cell, the state of charge values of each battery cell, and the timestamps at the corresponding time points, without using accurate cumulative capacity data, and thus the efficiency of battery detection is improved.

In some embodiments, the performing linear regression calculations based on the first matrix and the second matrix to obtain a regression result including a first regression coefficient and a second regression coefficient includes:
establishing a linear regression model, where the linear regression model includes a correspondence between a first regression coefficient, a second regression coefficient, the state of charge values of the reference battery cell, the state of charge values of each battery cell, and the timestamps at the corresponding time points; and
substituting the first matrix and the second matrix into the linear regression model for linear calculation to obtain the first regression coefficient and the second regression coefficient.

In the technical solution of these embodiments of this application, the corresponding relative battery capacity and relative self-discharge of each battery cell, the state of charge values of the reference battery cell, the state of charge values of each battery cell, and the timestamps at the corresponding time points are used as known parameters for solving the linear regression model to obtain the regression coefficients. Compared with a conventional calculation method, the method of this application improves the accuracy of calculation.

In some embodiments, the obtaining a positive correlation between the corresponding relative battery capacity and relative self-discharge of each battery cell and the state of charge values of the reference battery cell, the state of charge values of each battery cell, and the timestamps at the corresponding time points includes:
acquiring a first relational expression reflecting a capacity variation of the reference battery cell and acquiring a second relational expression reflecting a capacity variation of each battery cell; and
obtaining, based on the first relational expression and the second relational expression, a positive correlation between the corresponding relative battery capacity and relative self-discharge of each battery cell and the state of charge values of the reference battery cell, the state of charge values of each battery cell, and the timestamps at the corresponding time points.

In the technical solution of these embodiments of this application, the positive correlation between the corresponding relative battery capacity and relative self-discharge of each battery cell and the state of charge values of the reference battery cell, the state of charge values of each battery cell, and the timestamps at the corresponding time points is obtained based on the first relational expression reflecting the capacity variation of the reference battery cell and the second relational expression reflecting the capacity variation of each battery cell, so that the relative battery capacity and relative self-discharge can be obtained more conveniently and simply based on the charge of state values of the reference battery cell, the charge of state of charge values of each battery cell, and the timestamps at the corresponding time points, thereby improving the efficiency of battery detection.

In some embodiments, the obtaining, based on the first relational expression and the second relational expression, a positive correlation between the corresponding relative battery capacity and relative self-discharge of each battery cell and the state of charge values of the reference battery cell, the state of charge values of each battery cell, and the timestamps at the corresponding time points includes:
performing parameter transformation on the first relational expression and the second relational expression under a condition that the first relational expression is equal to the second relational expression; and
obtaining, based on a transformation result, a positive correlation between the corresponding relative battery capacity and relative self-discharge of each battery cell and the state of charge values of the reference battery cell, the state of charge values of each battery cell, and the timestamps at the corresponding time points.

In the technical solution of these embodiments of this application, the positive correlation between the corresponding relative battery capacity and relative self-discharge of each battery cell and the state of charge values of the reference battery cell, the state of charge values of each battery cell, and the timestamps at the corresponding time points is obtained using the characteristic that the battery cells in the battery system have the same discharge capacity, so that more accurate relative battery capacity and relative self-discharge can be further obtained.

In some embodiments, the acquiring a first relational expression reflecting a capacity variation of the reference battery cell and acquiring a second relational expression reflecting a capacity variation of each battery cell includes:
obtaining, based on a battery capacity of the reference battery cell, a charge variation of the reference battery cell, self-discharge of the reference battery cell, and standing time of the reference battery cell, a first relational expression reflecting a capacity variation of the reference battery cell; and
obtaining, based on the battery capacity of each battery cell, a charge variation of each battery cell, self-discharge of each battery cell, and standing time of each battery cell, a second relational expression reflecting a capacity variation of each battery cell.

In the technical solution of these embodiments of this application, a parameter relationship between the corresponding relative battery capacity and relative self-discharge of each battery cell in the linear regression model is obtained based on the established first relational expression and second relational expression, and the relative battery capacity and relative self-discharge can be directly obtained according to the parameter relationship, so that battery detection is implemented based on the reference battery cell, and the accuracy of battery detection is improved.

In some embodiments, the obtaining a consistency detection result of the battery cells in the battery system includes:
obtaining, based on the corresponding relative battery capacity and relative self-discharge of each battery cell, a variation in the battery capacity of each battery cell and the battery capacity of the reference battery cell in the battery system; and
obtaining a consistency detection result of the battery cells in the battery system based on the variation.

In the technical solution of these embodiments of this application, consistency detection of the battery is implemented based on the variation in the battery capacity of each battery cell and the battery capacity of the reference battery cell, and the accuracy of battery detection is improved.

In some embodiments, the obtaining, based on the corresponding relative battery capacity and relative self-discharge of each battery cell, a variation in the battery capacity of each battery cell and the battery capacity of the reference battery cell in the battery system includes: substituting the corresponding relative battery capacity and relative self-discharge of each battery cell with the regression result to obtain a correspondence between the first matrix and the second matrix;
obtaining, based on the correspondence between the first matrix and the second matrix, a target correspondence between the state of charge values of the battery cells and the state of charge values of the reference battery cell in the battery system; and
obtaining, based on the target correspondence, a variation in the battery capacity of each battery cell and the battery capacity of the reference battery cell in the battery system.

In the technical solution of these embodiments of this application, the state of charge values of the battery cells and the state of charge values of the reference battery cell in the battery system are retrodicted in the regression result based on the corresponding relative battery capacity and relative self-discharge of each battery cell, so that the variation in the battery capacity of each battery cell and the battery capacity of the reference battery cell is obtained, thereby implementing consistency detection of the battery and improving the accuracy of battery detection.

In some embodiments, the obtaining, based on the target correspondence, a variation in the battery capacity of each battery cell and the battery capacity of the reference battery cell in the battery system includes:
under a condition that the state of charge values of each battery cell in the battery system are first state of charge values, obtaining corresponding first reference state of charge values of the reference battery cell based on the target correspondence;
under a condition that the state of charge values of each battery cell in the battery system are second state of charge values, obtaining corresponding second reference state of charge values of the reference battery cell based on the correspondence, where the second state of charge value is less than the first state of charge value; and
using a difference value between the first reference state of charge value and the second reference state of charge value as a variation in the battery capacity of each battery cell and the battery capacity of the reference battery cell.

In the technical solution of these embodiments of this application, the variation in the battery capacity of each battery cell and the battery capacity of the reference battery cell is obtained based on the correspondence between the state of charge values of each battery cell and the state of charge values of the reference battery cell, so that consistency detection of the battery is implemented and the accuracy of battery detection is improved.

In some embodiments, the battery detection method further includes:
providing a warning under a condition that the corresponding relative battery capacity, relative self-discharge, and variation of each battery cell satisfy a preset warning condition.

In the technical solution of these embodiments of this application, under a condition that the preset warning condition is satisfied, warning is performed, so that the use safety of the battery is improved.

In some embodiments, the preset warning condition includes at least one of the following:
the corresponding relative battery capacity of each battery cell is less than a relative battery capacity threshold;
a capacity decrease speed of the corresponding relative battery capacity of each battery cell is greater than a decrease speed threshold within a relative battery capacity monitoring time;
the corresponding relative self-discharge of each battery cell is greater than a relative self-discharge threshold;
a self-discharge increase speed of the corresponding relative self-discharge of each battery cell is greater than an increase speed threshold within a relative self-discharge monitoring time; and
the variation in the battery capacity of each battery cell and the battery capacity of the reference battery cell in the battery system is greater than a variation threshold.

In the technical solution of these embodiments of this application, under a condition that the preset warning condition is satisfied, a warning is provided based on threshold comparison from multiple perspectives, so that effectiveness of battery detection is improved.

According to a second aspect, this application provides a battery cell detection apparatus, where the battery cell detection apparatus includes:
an acquiring module, configured to acquire state of charge values of each battery cell in a battery system at different time points within a preset time;
a selecting module, configured to select a reference battery cell from the battery cells; and
a regression analysis module, configured to perform multiple linear regression analysis based on state of charge values of the reference battery cell, the state of charge values of each battery cell, and timestamps at corresponding time points to obtain a consistency detection result of the battery cells in the battery system.

In technical solutions of embodiments of this application, a consistency detection result of the battery cells in the battery system is achieved by just selecting a reference battery cell from the battery cells and comparing the reference battery cell with the battery cells, without using accurate cumulative capacity data, obtaining a variation in the state of charge values based on the cumulative capacity data and obtaining the consistency detection result of the battery cells based on the variation in the state of charge values. Even without the capacity data, a relative result can be obtained through calculation, thus consistency of the battery cells is calculated, and the accuracy of battery detection is improved.

According to a third aspect, this application provides a battery cell detection device. The battery cell detection device includes a memory, a processor, and a battery detection program stored in the memory and capable of running on the processor, where the battery detection program is configured to implement the battery detection method as described above.

According to a fourth aspect, this application provides a storage medium, where a battery detection program is stored in the storage medium, and when the battery detection program is executed by a processor, the battery detection method as described above is implemented.

The foregoing descriptions are merely an overview of the technical solution of this application. For a better understanding of the technical means in this application such that they can be implemented according to the content of the specification, and to make the above and other objectives, features and advantages of this application more obvious and easier to understand, the following describes specific embodiments of this application.

### BRIEF DESCRIPTION OF DRAWINGS

FIG. 1 is a flowchart of a battery cell detection method according to some embodiments of this application;

FIG. 2 is a flowchart of a battery cell detection method according to some other embodiments of this application;

FIG. 3 is an overall schematic flowchart of a battery cell detection method according to some embodiments of this application; and

FIG. 4 is a schematic structural diagram of a battery cell detection apparatus according to some embodiments of this application.

### DESCRIPTION OF EMBODIMENTS

The following describes in detail the embodiments of technical solutions of this application with reference to the accompanying drawings. The following embodiments are merely intended for a clearer description of the technical solutions of this application and therefore are merely used as examples which do not constitute any limitation on the protection scope of this application.

Unless otherwise defined, all technical and scientific terms used herein shall have the same meanings as commonly understood by persons skilled in the art to which this application pertains. The terms used herein are intended to merely describe the specific embodiments rather than to limit this application. The terms “include”, “comprise”, and any other variations thereof in the specification, claims and brief description of drawings of this application are intended to cover non-exclusive inclusions.

In the descriptions of the embodiments of this application, the technical terms “first”, “second”, and the like are merely intended to distinguish between different objects, and shall not be understood as any indication or implication of relative importance or any implicit indication of the number, specific sequence, or primary-secondary relationship of the technical features indicated. In the descriptions of the embodiments of this application, “multiple” means more than two, unless otherwise specifically defined.

In this specification, reference to “embodiment” means that specific features, structures or characteristics described with reference to the embodiment may be incorporated in at least one embodiment of this application. The word “embodiment” appearing in various places in the specification does not necessarily refer to the same embodiment or an independent or alternative embodiment that is exclusive of other embodiments. It is explicitly or implicitly understood by persons skilled in the art the embodiments described herein may be combined with other embodiments.

In the description of the embodiments of this application, the term “and/or” is only an associative relationship for describing associated objects, indicating that three relationships may be present. For example, A and/or B may indicate the following three cases: presence of only A, presence of both A and B, and presence of only B. In addition, the character “/” in this specification generally indicates an “or” relationship between the contextually associated objects.

In the descriptions of the embodiments of this application, the term “multiple” means more than two (inclusive). Similarly, “multiple groups” means more than two (inclusive) groups, and “multiple pieces” means more than two (inclusive) pieces.

In the description of the embodiments of this application, the orientations or positional relationships indicated by the technical terms “center”, “longitudinal”, “transverse”, “length”, “width”, “thickness”, “upper”, “lower”, “front”, “rear”, “left”, “right”, “vertical”, “horizontal”, “top”, “bottom”, “inside”, “outside”, “clockwise”, “counterclockwise”, “axial”, “radial”, “circumferential”, and the like are based on the orientations or positional relationships as shown in the accompanying drawings. These terms are merely for ease and brevity of description of the embodiments of this application rather than indicating or implying that the means or components mentioned must have specific orientations or must be constructed or manipulated according to specific orientations, and therefore shall not be construed as any limitation on the embodiments of this application.

In the description of the embodiments of this application, unless otherwise specified and defined explicitly, the terms “mounting”, “connection”, “join”, and “fastening” should be understood in their general senses. For example, they may refer to a fixed connection, a detachable connection, or an integral connection, may refer to a mechanical connection or electrical connection, and may refer to a direct connection, an indirect connection via an intermediate medium, an internal communication between two elements, or an interaction between two elements. Persons of ordinary skill in the art can understand specific meanings of these terms in the embodiments of this application as appropriate to specific situations. The specific embodiments described herein are merely intended to explain the present disclosure rather than limit the present disclosure.

Generally, to implement consistency detection of battery packs, it is needed to separately calculate the capacity/self-discharge of each battery cell. However, it is unable to record a significant amount of historical data in a BMS battery management system for capacity/self-discharge calculation. It is easier to implement the calculation in cloud, but obtaining accurate cumulative capacity data in cloud is often challenging. Therefore, more accurate consistency detection of battery packs cannot be performed.

To resolve the existing problem that more accurate consistency detection of battery packs cannot be performed, in the embodiments of this application, a consistency detection result of the battery cells in the battery system is achieved by just selecting a reference battery cell from the battery cells and comparing the reference battery cell with the battery cells, without using accurate cumulative capacity data, obtaining a variation in the state of charge values based on the cumulative capacity data and obtaining the consistency detection result of the battery cells based on the variation in the state of charge values. Even without the capacity data, a relative result can be obtained through calculation, thus consistency of the battery cells is calculated, and the accuracy of battery detection is improved.

The battery cell disclosed in the embodiments of this application may be used for electric apparatuses that use a battery as a power source or various energy storage systems that use a battery as an energy storage element. The electric apparatus may be but is not limited to a mobile phone, a tablet computer, a laptop computer, an electric toy, an electric tool, an electric bicycle, an electric vehicle, a ship, and a spacecraft. The electric toy may be a fixed or mobile electric toy, for example, a game console, an electric toy car, an electric toy ship, and an electric toy airplane. The spacecraft may include an airplane, a rocket, a space shuttle, a spaceship, and the like.

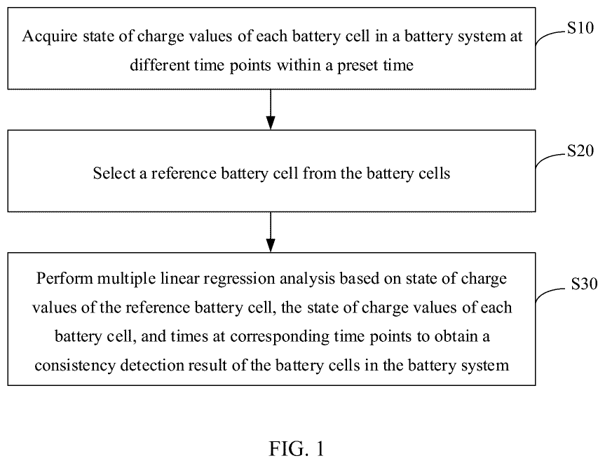

To resolve the existing problem that more accurate consistency detection of battery packs cannot be performed, this application proposes a battery detection method. Referring to FIG. 1, in the example, the battery detection method includes the following steps.

Step S10. Acquire state of charge values of each battery cell in a battery system at different time points within a preset time.

It should be noted that this embodiment may be executed by a controller in the battery system or another service processor, and this is not limited in this embodiment. In this embodiment, the controller in the battery system is used as an example for description, where the preset time may be 1 day or 1 hour, and this is not limited in this embodiment. In an example in which the preset time is 1 day, the state of charge values of each battery cell in the battery system at different time points within the preset time are acquired, that is, SOC values, to provide data support for subsequent linear calculation. Generally, state of charge values are usually obtained through calculation based on an open circuit voltage of a battery after standing.

In a specific implementation, a sensor is used to acquire data such as current, voltage, and temperature of the battery. The sensor is connected to the controller in the battery system and transmits the acquired data such as current, voltage, and temperature of the battery to the controller in the battery system. After obtaining the data such as current, voltage, and temperature of the battery, the controller screens the data such as current, voltage, and temperature of the battery to obtain data satisfying a condition of the open circuit voltage, that is, open circuit voltage data of the battery after a certain time of full standing. In this way, the detection accuracy is improved. The controller in the battery system obtains state of charge values at different time points based on the open circuit voltage of the battery after standing that is acquired by the sensor, thereby implementing automatic data acquisition.

Step S20. Select a reference battery cell from the battery cells.

In this embodiment, the reference battery cell may be one battery cell selected from the battery cells in the battery system. The reference battery cell may be selected randomly or selected in a default manner. Alternatively, an average value of the battery may be used as a virtual reference battery. This is not limited in this embodiment. One reference battery cell is selected using the characteristic that the battery cells in the battery system have the same discharge capacity, a battery capacity variation ΔAh of the reference battery cell is used to replace ΔAh of all the other battery cells, so that consistency detection of the battery can be implemented without capacity information, avoiding errors in detection results caused by miscalculation of the capacity information, thereby improving the accuracy of battery detection.

Step S30. Perform multiple linear regression analysis based on state of charge values of the reference battery cell, the state of charge values of each battery cell, and timestamps at corresponding time points to obtain a consistency detection result of the battery cells in the battery system.

It should be noted that the state of charge values of the reference battery cell are represented by SOC_{ref}, the state of charge values of each battery cell are represented by SOCₙ, and the timestamps at corresponding time points is represented by Time, where SOC_{ref}, SOCₙ, and Time are used for multiple linear regression analysis, and consistency detection of the battery cells in the battery system can be implemented without ΔAh and state of charge value variation ΔSOC.

Generally, battery capacity, self-discharge, and state of equilibrium are important characteristic parameters of battery packs. The consistency of a battery system is measured based on the battery capacity, self-discharge, and state of equilibrium. In consistency detection of battery cells, capacity differences of the battery cells in the battery system are detected. In this embodiment, consistency detection of the battery cells is implemented using the reference battery cell. Therefore, multiple linear regression analysis is performed based on the state of charge values of the reference battery cell, the state of charge values of each battery cell, and timestamps at corresponding time points to obtain the relative battery capacity and relative self-discharge of each battery cell, and consistency detection of the battery cells is implemented based on the relative battery capacity and relative self-discharge of each battery cell, so that the original consistency detection manner of the battery is changed, and the consistency detection of the battery is performed in a totally new manner. In this way, the consistency detection of the battery can be implemented without capacity information, avoiding errors in detection results caused by miscalculation of the capacity information, thereby improving the accuracy of battery detection.

In technical solutions of embodiments of this application, a consistency detection result of the battery cells in the battery system is achieved by just selecting a reference battery cell from the battery cells and comparing the reference battery cell with the battery cells, without using accurate cumulative capacity data, obtaining a variation in the state of charge values based on the cumulative capacity data and obtaining the consistency detection result of the battery cells based on the variation in the state of charge values. Even without the capacity data, a relative result can be obtained through calculation, thus consistency of the battery cells is calculated, and the accuracy of battery detection is improved.

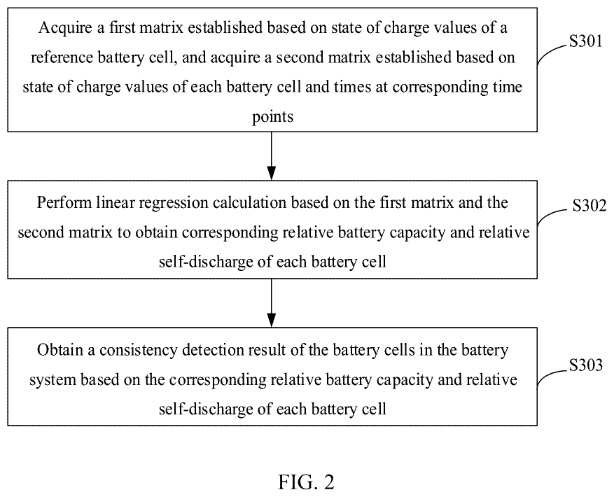

A second embodiment of the present disclosure is proposed based on the first embodiment. In the second embodiment, as shown in FIG. 2, step S30 includes the following steps.

Step S301. Acquire a first matrix established based on state of charge values of the reference battery cell, and acquire a second matrix established based on the state of charge values of each battery cell and timestamps at corresponding time points.

Step S302. Perform linear regression calculations based on the first matrix and the second matrix to obtain corresponding relative battery capacity and relative self-discharge of each battery cell.

Step S303. Obtain a consistency detection result of the battery cells in the battery system based on the corresponding relative battery capacity and relative self-discharge of each battery cell.

It should be noted that the first matrix Y established based on the state of charge values of the reference battery cell is:

$$Y = [ \begin{matrix}{SOC}_{ref 1} \\ {SOC}_{ref 2} \\ ⋮ \\ {SOC}_{reft}\end{matrix} ] ;$$

where SOC_{reft} represents the state of charge values of the reference battery cell at 1-t time points, respectively.

The second matrix X established based on the state of charge values of each battery cell and timestamps at corresponding time points is:

$$X = [ \begin{matrix}1 & {SOC}_{n 1} & {Time}_{1} \\ 1 & {SOC}_{n 2} & {Time}_{2} \\ ⋮ & ⋮ & ⋮ \\ 1 & {SOC}_{nt} & {Time}_{t}\end{matrix} ] ;$$

where SOCₙₜ represents the state of charge values of a battery cell whose number is n in the battery system at 1-t time points, and Timeₜ represents the timestamps corresponding to the 1-t time points of each battery cell.

In a specific implementation, data at different time points within a certain time window, including time and the selected reference battery cell, are collected to obtain X and Y that are inputted into matrices (for example, there are t pieces of data), and linear regression calculations are performed based on the first matrix and the second matrix to obtain corresponding relative battery capacity and relative self-discharge of each battery cell.

Linear regression calculations are performed to obtain a result:

$$β = {( {X}^{T} X )}^{- 1} {X}^{T} Y = [ \begin{matrix}{β}_{1} \\ {β}_{2} \\ {β}_{3}\end{matrix} ] ; \qquad Formula 1$$

where β₁ represents an intercept, β₂ represents a relative capacity of each battery cell, and β₃ represents a relative self-discharge of each battery cell.

$$Relative capacity : \frac{{CAP}_{n}}{{CAP}_{ref}} = {β}_{2} ; and$$

$$relative self - discharge : \frac{{SlfDch}_{n} - {SlfDch}_{ref}}{{CAP}_{rep}} = {β}_{3} ;$$

where CAPₙ represents the capacity of each battery cell, CAP_{ref} represents the capacity of the reference battery cell, slfDchₙ represents the self-discharge of each battery cell, and slfDch_{ref} represents the self-discharge of the reference battery cell.

In this embodiment, the corresponding relative battery capacity and relative self-discharge of each battery cell are obtained based on the state of charge values of the reference battery cell, the state of charge values of each battery cell, and the timestamps at the corresponding time points. In this way, the corresponding relative battery capacity and relative self-discharge of each battery cell are obtained using the characteristic that the battery cells in the battery system have the same discharge capacity, without using accurate cumulative capacity data, and thus the accuracy of battery detection is improved.

According to some embodiments of this application, optionally, step S302 includes:
performing linear regression calculations based on the first matrix and the second matrix to obtain a regression result including a first regression coefficient and a second regression coefficient; and
using the first regression coefficient as a corresponding relative battery capacity of each battery cell and using the second regression coefficient as a corresponding relative self-discharge of each battery cell based on the regression result.

It should be noted that the first regression coefficient is β₂, and the second regression coefficient is β₃. In an established linear relationship between the first matrix and the second matrix, known input parameters are SOC_{reft}, SOCₙₜ, and Timeₜ, and a linear model related to SOC_{reft}, SOCₙₜ, and Timeₜ is obtained based on linear calculation.

Under a condition that a positive correlation between the corresponding relative battery capacity and relative self-discharge of each battery cell and the state of charge values of the reference battery cell, the state of charge values of each battery cell, and the timestamps at the corresponding time points is statistically calculated, the correlation thereof is:

$${SOC}_{ref} = \frac{{CAP}_{n}}{{CAP}_{ref}} \times {SOC}_{n} + \frac{{slfDch}_{n} - {slfDch}_{ref}}{{CAP}_{ref}} \times time + Intercept ; \qquad Formula 2$$

where Intercept represents an intercept.

A relationship between

$$\frac{{CAP}_{n}}{{CAP}_{ref}} , \frac{{slfDch}_{n} - {slfDch}_{ref}}{{CAP}_{ref}} ,$$

SOC_{ref}, SOCₙ, and Time is obtained based on the positive correlation, so that a correspondence between regression coefficients obtained by solving Formula 1 and coefficients formed by

$$\frac{{CAP}_{n}}{{CAP}_{ref}} and \frac{{slfDch}_{n} - {slfDch}_{ref}}{{CAP}_{ref}}$$

in Formula 2 can be obtained.

It can be seen that the following can be obtained:

$$\frac{{CAP}_{n}}{{CAP}_{ref}} = {β}_{2} ; and$$

$$\frac{{SlfDch}_{n} - {SlfDch}_{ref}}{{CAP}_{rep}} = {β}_{3} ;$$

where β₂ represents a relative capacity of each battery cell, and β₃ represents a relative self-discharge of each battery cell.

In the technical solution of these embodiments of this application, the corresponding relative battery capacity and relative self-discharge of each battery cell are obtained based on the statistically calculated positive correlation between the corresponding relative battery capacity and relative self-discharge of each battery cell and the state of charge values of the reference battery cell, the state of charge values of each battery cell, and the timestamps at the corresponding time points, without using accurate cumulative capacity data, and thus the efficiency of battery detection is improved.

According to some embodiments of this application, optionally, the performing linear regression calculations based on the first matrix and the second matrix to obtain a regression result including a first regression coefficient and a second regression coefficient includes:
establishing a linear regression model, where the linear regression model includes a correspondence between a first regression coefficient, a second regression coefficient, the state of charge values of the reference battery cell, the state of charge values of each battery cell, and the timestamps at the corresponding time points; and
substituting the first matrix and the second matrix into the linear regression model for linear calculation to obtain the first regression coefficient and the second regression coefficient.

In these embodiments, the linear regression model is denoted as Formula 1, and Formula 1 can be solved to obtain the first regression coefficient and the second regression coefficient, so as to obtain the corresponding relative battery capacity and relative self-discharge of each battery cell, without using accurate cumulative capacity data. In this way, the calculation accuracy is improved.

According to some embodiments of this application, optionally, the obtaining a positive correlation between the corresponding relative battery capacity and relative self-discharge of each battery cell and the state of charge values of the reference battery cell, the state of charge values of each battery cell, and the timestamps at the corresponding time points includes:
acquiring a first relational expression reflecting a capacity variation of the reference battery cell and acquiring a second relational expression reflecting a capacity variation of each battery cell; and
obtaining, based on the first relational expression and the second relational expression, a positive correlation between the corresponding relative battery capacity and relative self-discharge of each battery cell and the state of charge values of the reference battery cell, the state of charge values of each battery cell, and the timestamps at the corresponding time points.

The first relational expression is:

$${CAP}_{ref} \times Δ {SOC}_{ref} + {slfDch}_{ref} \times time . \qquad Formula 3$$

The second relational expression is:

$${CAP}_{n} \times Δ {SOC}_{n} + {slfDch}_{n} \times time + Intercept . \qquad Formula 4$$

In these embodiments, the positive correlation between the corresponding relative battery capacity and relative self-discharge of each battery cell and the state of charge values of the reference battery cell, the state of charge values of each battery cell, and the timestamps at the corresponding time points is obtained based on the first relational expression reflecting the capacity variation of the reference battery cell and the second relational expression reflecting the capacity variation of each battery cell, so that the relative battery capacity and relative self-discharge can be obtained more conveniently and simply based on the charge of state values of the reference battery cell, the charge of state of charge values of each battery cell, and the timestamps at the corresponding time points, thereby improving the efficiency of battery detection.

According to some embodiments of this application, optionally, the obtaining, based on the first relational expression and the second relational expression, a positive correlation between the corresponding relative battery capacity and relative self-discharge of each battery cell and the state of charge values of the reference battery cell, the state of charge values of each battery cell, and the timestamps at the corresponding time points includes:
performing parameter transformation on the first relational expression and the second relational expression under a condition that the first relational expression is equal to the second relational expression; and
obtaining, based on a transformation result, a positive correlation between the corresponding relative battery capacity and relative self-discharge of each battery cell and the state of charge values of the reference battery cell, the state of charge values of each battery cell, and the timestamps at the corresponding time points.

In a specific implementation, the battery cells in the battery system have the same discharge capacity. Therefore, the first relational expression is equal to the second relational expression. To be specific, the following is obtained based on Formula 3 and Formula 4:

$${CAP}_{ref} \times Δ {SOC}_{ref} + {slfDch}_{ref} \times time = {CAP}_{n} \times Δ {SOC}_{n} + {slfDch}_{n} \times time + Intercept . \qquad Formula 5$$

The following is obtained through transformation:

$${SOC}_{ref} = \frac{{CAP}_{n}}{{CAP}_{ref}} \times {SOC}_{n} + \frac{{slfDch}_{n} - {slfDch}_{ref}}{{CAP}_{ref}} \times time + Intercept .$$

In this way, a positive correlation between SOC_{reft}, SOCₙₜ, Timeₜ,

$$\frac{{CAP}_{n}}{{CAP}_{ref}} , and \frac{{slfDch}_{n} - {slfDch}_{ref}}{{CAP}_{ref}}$$

is obtained.

In this application, the positive correlation between the corresponding relative battery capacity and relative self-discharge of each battery cell and the state of charge values of the reference battery cell, the state of charge values of each battery cell, and the timestamps at the corresponding time points is obtained using the characteristic that the battery cells in the battery system have the same discharge capacity, so that more accurate relative battery capacity and relative self-discharge can be further obtained.

According to some embodiments of this application, optionally, the acquiring a first relational expression reflecting a capacity variation of the reference battery cell and acquiring a second relational expression reflecting a capacity variation of each battery cell includes:
obtaining, based on a battery capacity of the reference battery cell, a charge variation of the reference battery cell, self-discharge of the reference battery cell, and standing time of the reference battery cell, a first relational expression reflecting a capacity variation of the reference battery cell; and
obtaining, based on the battery capacity of each battery cell, a charge variation of each battery cell, self-discharge of each battery cell, and standing time of each battery cell, a second relational expression reflecting a capacity variation of each battery cell.

The first relational expression is:

$${CAP}_{ref} \times Δ {SOC}_{ref} + {slfDch}_{ref} \times time .$$

The second relational expression is:

$${CAP}_{n} \times Δ {SOC}_{n} + {slfDch}_{n} \times time + Intercept .$$

In these embodiments, a parameter relationship between the corresponding relative battery capacity and relative self-discharge of each battery cell in the linear regression model is obtained based on the established first relational expression and second relational expression, and the relative battery capacity and relative self-discharge can be directly obtained according to the parameter relationship, so that battery detection is implemented based on the reference battery cell, and the accuracy of battery detection is improved.

According to some embodiments of this application, optionally, the obtaining a consistency detection result of the battery cells in the battery system includes:
obtaining, based on the corresponding relative battery capacity and relative self-discharge of each battery cell, a variation in the battery capacity of each battery cell and the battery capacity of the reference battery cell in the battery system; and
obtaining a consistency detection result of the battery cells in the battery system based on the variation.

In these embodiments, the variation in the battery capacity of each battery cell and the battery capacity of the reference battery cell in the battery system is a difference value between the battery capacity of each battery cell and the battery capacity of the reference battery cell in the battery system. Based on the difference value between the battery capacity of each battery cell and the battery capacity of the reference battery cell, capacity differences between the battery cells can be obtained, and thus a consistency detection result of the battery cells in the battery system can be obtained.

According to some embodiments of this application, optionally, the obtaining, based on the corresponding relative battery capacity and relative self-discharge of each battery cell, a variation in the battery capacity of each battery cell and the battery capacity of the reference battery cell in the battery system includes:
substituting a regression result corresponding to the corresponding relative battery capacity and relative self-discharge of each battery cell into a third relational expression to obtain a correspondence between the state of charge values of each battery cell and the state of charge values of the reference battery cell; and obtaining, based on the correspondence, a variation in the battery capacity of each battery cell and the battery capacity of the reference battery cell in the battery system.

The calculated regression result of each battery cell is substituted into Formula 6 to obtain a correspondence between state of charge of each battery and state of charge of the reference battery. A correspondence between the state of charge of each battery and the state of charge of the reference battery in a fully charged state and a fully discharged state respectively, and an available state of charge range in the battery system is calculated based on the correspondence, where a third relational expression is shown in Formula 6.

$${SOC}_{ref} = [ \begin{matrix}1 & {SOC}_{n} & {Time}_{now} ]\end{matrix} β ; \qquad Formula 6$$

where Time_{now} represents a current time point.

The variation in the battery capacity of each battery cell and the battery capacity of the reference battery cell can be obtained based on the target correspondence, and a relative relationship between the capacity of the battery system and the capacity of the reference battery is further obtained, thereby implementing detection of the state of equilibrium.

In this application, the state of charge values of the battery cells and the state of charge values of the reference battery cell in the battery system are retrodicted in the regression result based on the corresponding relative battery capacity and relative self-discharge of each battery cell, so that the variation in the battery capacity of each battery cell and the battery capacity of the reference battery cell is obtained, and the relative relationship between the capacity of the battery system and the capacity of the reference battery is further obtained, thereby implementing consistency detection of the battery and improving the accuracy of battery detection.

According to some embodiments of this application, optionally, the obtaining, based on the target correspondence, a variation in the battery capacity of each battery cell and the battery capacity of the reference battery cell in the battery system includes:
under a condition that the state of charge values of each battery cell in the battery system are first state of charge values, obtaining corresponding first reference state of charge values of the reference battery cell based on the target correspondence; under a condition that the state of charge values of each battery cell in the battery system are second state of charge values, obtaining corresponding second reference state of charge values of the reference battery cell based on the correspondence, where the second state of charge value is less than the first state of charge value; and using a difference value between the first reference state of charge value and the second reference state of charge value as a variation in the battery capacity of each battery cell and the battery capacity of the reference battery cell.

In these embodiments, in calculation of the state of equilibrium, for example, m battery cells are provided in the battery system, a relative relationship between an available capacity of the battery system and the capacity of the reference battery cell within a range of 0 to 100% is calculated; at the current time point Time_{now}, the first state of charge value is a state of charge value SOC_{ref_n_100%}==[1 100% Time_{now}]·β of the reference battery cell when SOCₙ is 100%, obtained according to Formula 6 under a condition that the state of charge value of each battery cell is 100%, that is, 100% SOC, SOCₙ is 100%, and the corresponding relative battery capacity and relative self-discharge of each battery cell is β; a minimum value of the state of charge values of all the battery cells in the system is SOC_{ref_hi}=min(SOC_{ref_1_100%}, SOC_{ref_2_100%} . . . SOC_{ref_m_100%}); and the first reference state of charge value is obtained as SOC_{ref_hi}.

Similarly, the second state of charge value is a state of charge value SOC_{ref_n_0%}==[1 0 Time_{now}]β of the reference battery cell when SOCₙ is 0, obtained according to Formula 6 under a condition that the state of charge value of each battery cell is 0, that is, 0SOC, SOCₙ is 0SOC, and the corresponding relative battery capacity and relative self-discharge of each battery cell is β; a maximum value of the state of charge values of all the battery cells in the system is SOC_{ref_lo}=max(SOC_{ref_1_0%}, SOC_{ref_2_0%} . . . SOC_{ref_m_0%}); and the second reference state of charge value is obtained as SOC_{ref_lo}.

Therefore, the available capacity of the battery system decreases with respect to the capacity of the reference battery cell: 100%−SOC_{ref_hi}+SOC_{ref_lo}, so that the variation in the available capacity of the battery system and the battery capacity of the reference battery cell is obtained.

In this application, the variation in the battery capacity of each battery cell and the battery capacity of the reference battery cell is obtained based on the correspondence between the state of charge values of each battery cell and the state of charge values of the reference battery cell, thereby implementing consistency detection of the battery and improving the accuracy of battery detection.

According to some embodiments of this application, optionally, the battery detection method further includes:
providing a warning under a condition that the corresponding relative battery capacity, relative self-discharge, and variation of each battery cell satisfy a preset warning condition.

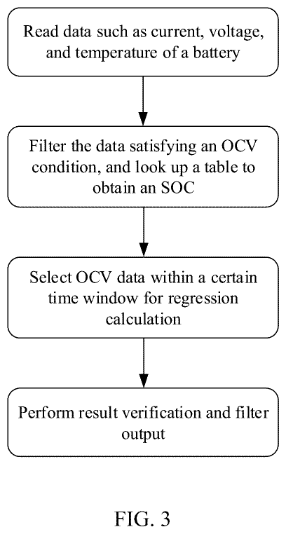

As shown in the overall schematic flowchart in FIG. 3, the following steps are mainly included.

Step 1. Read data such as current, voltage, and temperature of the battery, excluding capacity data.

Step 2. Filter the data satisfying an OCV condition, and consider that the battery satisfies the OCV condition after it undergoes a certain time of full standing.

Step 3. Select multiple pieces of OCV data within a certain time window for regression calculation.

Step 4. Obtain a consistency result of the battery.

Step 5. Provide a capacity consistency warning for a battery whose relative capacity is low or relative capacity decrease speed is too high; provide a self-discharge consistency warning for a battery whose relative self-discharge is high or relative self-discharge increase speed is too high; and calculate the capacity of the battery system based on the capacity of the battery cell.

According to some embodiments of this application, optionally, the preset warning condition includes at least one of the following:
the corresponding relative battery capacity of each battery cell is less than a relative battery capacity threshold;
a capacity decrease speed of the corresponding relative battery capacity of each battery cell is greater than a decrease speed threshold within a relative battery capacity monitoring time;
the corresponding relative self-discharge of each battery cell is greater than a relative self-discharge threshold;
a self-discharge increase speed of the corresponding relative self-discharge of each battery cell is greater than an increase speed threshold within a relative self-discharge monitoring time; and
the variation in the battery capacity of each battery cell and the battery capacity of the reference battery cell in the battery system is greater than a variation threshold.

In this application, under a condition that the preset warning condition is satisfied, a warning is provided based on threshold comparison from multiple perspectives, so that effectiveness of battery detection is improved.

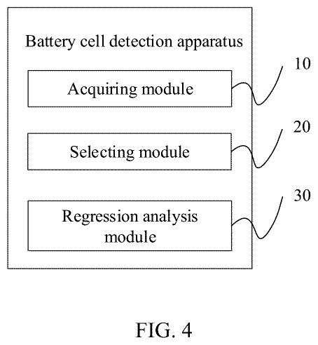

According to some embodiments of this application, referring to FIG. 4, FIG. 4 is a schematic structural diagram of a battery cell detection apparatus according to some embodiments of this application.

In these embodiments, the battery cell detection apparatus includes:
an acquiring module 10, configured to acquire state of charge values of each battery cell in a battery system at different time points within a preset time;
a selecting module 20, configured to select a reference battery cell from the battery cells; and
a regression analysis module 30, configured to perform multiple linear regression analysis based on state of charge values of the reference battery cell, the state of charge values of each battery cell, and timestamps at corresponding time points to obtain a consistency detection result of the battery cells in the battery system.

In this application, a consistency detection result of the battery cells in the battery system is achieved by just selecting the reference battery cell from the battery cells and comparing the reference battery cell with the battery cells, without using cumulative capacity data, obtaining a variation in the state of charge values based on the cumulative capacity data and obtaining the consistency detection result of the battery cells based on the variation in the state of charge values. Even without the capacity data, a relative result can be obtained through calculation, thus consistency of the battery cells is calculated, and the accuracy of battery detection is improved.

In conclusion, it should be noted that the foregoing embodiments are merely for describing the technical solutions of this application rather than for limiting this application. Although this application has been described in detail with reference to the foregoing embodiments, persons of ordinary skill in the art should appreciate that they can still make modifications to the technical solutions described in the embodiments or make equivalent replacements to some or all technical features thereof without departing from the scope of the technical solutions of the embodiments of this application. All such modifications and equivalent replacements shall fall within the scope of claims and specification of this application. In particular, as long as there is no structural conflict, the various technical features mentioned in the embodiments can be combined in any manner. This application is not limited to the specific embodiments disclosed in this specification, but includes all technical solutions falling within the scope of the claims.

What is claimed is:

1. A battery detection method, comprising:
acquiring state of charge values of each battery cell in a battery system at different time points within a preset time;
selecting a reference battery cell from the battery cells; and
performing multiple linear regression analysis based on state of charge values of the reference battery cell, the state of charge values of each battery cell, and timestamps at corresponding time points to obtain a consistency detection result of the battery cells in the battery system.

2. The battery detection method according to claim 1, wherein performing multiple linear regression analysis based on the state of charge values of the reference battery cell, the state of charge values of each battery cell, and the timestamps at the corresponding time points to obtain the consistency detection result of the battery cells in the battery system comprises:
acquiring a first matrix established based on state of charge values of the reference battery cell, and acquiring a second matrix established based on the state of charge values of each battery cell and timestamps at corresponding time points;
performing linear regression calculations based on the first matrix and the second matrix to obtain corresponding relative battery capacity and relative self-discharge of each battery cell; and
obtaining a consistency detection result of the battery cells in the battery system based on the corresponding relative battery capacity and relative self-discharge of each battery cell.

3. The battery detection method according to claim 2, wherein performing linear regression calculations based on the first matrix and the second matrix to obtain the corresponding relative battery capacity and the relative self-discharge of each battery cell comprises:
performing linear regression calculations based on the first matrix and the second matrix to obtain a regression result including a first regression coefficient and a second regression coefficient; and
using the first regression coefficient as a corresponding relative battery capacity of each battery cell and using the second regression coefficient as a corresponding relative self-discharge of each battery cell based on the regression result.

4. The battery detection method according to claim 3, wherein performing linear regression calculations based on the first matrix and the second matrix to obtain the regression result comprising the first regression coefficient and the second regression coefficient comprises:
establishing a linear regression model, where the linear regression model includes a correspondence between a first regression coefficient, a second regression coefficient, the state of charge values of the reference battery cell, the state of charge values of each battery cell, and the timestamps at the corresponding time points; and
substituting the first matrix and the second matrix into the linear regression model for linear calculation to obtain the first regression coefficient and the second regression coefficient.

5. The battery detection method according to claim 1, further comprising:
acquiring a first relational expression reflecting a capacity variation of the reference battery cell and acquiring a second relational expression reflecting a capacity variation of each battery cell; and
obtaining, based on the first relational expression and the second relational expression, a positive correlation between the corresponding relative battery capacity and relative self-discharge of each battery cell and the state of charge values of the reference battery cell, the state of charge values of each battery cell, and the timestamps at the corresponding time points.

6. The battery detection method according to claim 5, wherein obtaining, based on the first relational expression and the second relational expression, the positive correlation between the corresponding relative battery capacity and relative self-discharge of each battery cell and the state of charge values of the reference battery cell, the state of charge values of each battery cell, and the timestamps at the corresponding time points comprises:
performing parameter transformation on the first relational expression and the second relational expression under a condition that the first relational expression is equal to the second relational expression; and
obtaining, based on a transformation result, a positive correlation between the corresponding relative battery capacity and relative self-discharge of each battery cell and the state of charge values of the reference battery cell, the state of charge values of each battery cell, and the timestamps at the corresponding time points.

7. The battery detection method according to claim 5, wherein acquiring the first relational expression reflecting the capacity variation of the reference battery cell and acquiring the second relational expression reflecting the capacity variation of each battery cell comprises:
obtaining, based on a battery capacity of the reference battery cell, a charge variation of the reference battery cell, self-discharge of the reference battery cell, and timestamps at corresponding time points of the reference battery cell, a first relational expression reflecting a capacity variation of the reference battery cell; and
obtaining, based on the battery capacity of each battery cell, a charge variation of each battery cell, self-discharge of each battery cell, and standing time of each battery cell, a second relational expression reflecting a capacity variation of each battery cell.

8. The battery detection method according to claim 3, wherein obtaining the consistency detection result of the battery cells in the battery system comprises:
obtaining, based on the corresponding relative battery capacity and relative self-discharge of each battery cell, a variation in the battery capacity of each battery cell and the battery capacity of the reference battery cell in the battery system; and
obtaining a consistency detection result of the battery cells in the battery system based on the variation.

9. The battery detection method according to claim 8, wherein obtaining, based on the corresponding relative battery capacity and relative self-discharge of each battery cell, the variation in the battery capacity of each battery cell and the battery capacity of the reference battery cell in the battery system comprises:
substituting a regression result corresponding to the corresponding relative battery capacity and relative self-discharge of each battery cell into a third relational expression to obtain a correspondence between the state of charge values of each battery cell and the state of charge values of the reference battery cell; and
obtaining, based on the correspondence, a variation in the battery capacity of each battery cell and the battery capacity of the reference battery cell in the battery system.

10. The battery detection method according to claim 9, wherein obtaining, based on the correspondence, the variation in the battery capacity of each battery cell and the battery capacity of the reference battery cell in the battery system comprises:
under a condition that the state of charge values of each battery cell in the battery system are first state of charge values, obtaining corresponding first reference state of charge values of the reference battery cell based on the correspondence;
under a condition that the state of charge values of each battery cell in the battery system are second state of charge values, obtaining corresponding second reference state of charge values of the reference battery cell based on the correspondence, wherein the second state of charge value is less than the first state of charge value; and
using a difference value between the first reference state of charge value and the second reference state of charge value as a variation in the battery capacity of each battery cell and the battery capacity of the reference battery cell.

11. The battery detection method according to claim 8, further comprising:
providing a warning under a condition that the corresponding relative battery capacity, relative self-discharge, and variation of each battery cell satisfy a preset warning condition.

12. The battery detection method according to claim 11, wherein the preset warning condition comprises at least one of following:
the corresponding relative battery capacity of each battery cell is less than a relative battery capacity threshold;
a capacity decrease speed of the corresponding relative battery capacity of each battery cell is greater than a decrease speed threshold within a relative battery capacity monitoring time;
the corresponding relative self-discharge of each battery cell is greater than a relative self-discharge threshold;
a self-discharge increase speed of the corresponding relative self-discharge of each battery cell is greater than an increase speed threshold within a relative self-discharge monitoring time; and
the variation in the battery capacity of each battery cell and the battery capacity of the reference battery cell in the battery system is greater than a variation threshold.

13. A battery detection device, comprising:
a processor; and
a memory storing a battery detection program that, when executed by the processor, causes the processor to implement the battery detection method according to claim 1.

14. A storage medium, storing a battery detection program that, when executed by a processor, causes the processor to implement the battery detection method according to claim 1.

15. A battery detection apparatus, comprising:
an acquiring module, configured to acquire state of charge values of each battery cell in a battery system at different time points within a preset time;
a selecting module, configured to select a reference battery cell from the battery cells; and
a regression analysis module, configured to perform multiple linear regression analysis based on state of charge values of the reference battery cell, the state of charge values of each battery cell, and timestamps at corresponding time points to obtain a consistency detection result of the battery cells in the battery system.
